(19) United States
(12) Patent Application Publication
(10) Pub. No.: US 2025/0357285 A1
(43) Pub. Date: Nov. 20, 2025

(54) SEMICONDUCTOR DEVICE

(71) Applicant: Mitsubishi Electric Corporation, Tokyo (JP)

(72) Inventors: Masafumi OYAMA, Tokyo (JP); Narumi MATSUSHITA, Tokyo (JP)

(73) Assignee: Mitsubishi Electric Corporation, Tokyo (JP)

(21) Appl. No.: 19/199,313

(22) Filed: May 5, 2025

(30) Foreign Application Priority Data
May 20, 2024 (JP) 2024-081897

(51) Int. Cl. H01L 23/495; H01L 23/00; H01L 23/31; H01L 25/18; H10D 80/20

(52) U.S. Cl. CPC H01L 23/49562; H01L 24/32; H01L 24/48; H01L 24/73; H01L 25/18; H01L 23/3121; H01L 2224/32245; H01L 2224/48137; H01L 2224/48245; H01L 2224/73265; H01L 2924/10253; H01L 2924/10272; H01L 2924/13055; H01L 2924/13091; H10D 80/251

(57) ABSTRACT

Provided is a semiconductor device that can suppress deterioration of assemblability and can achieve downsizing. The semiconductor device includes a base member, a first semiconductor element, and a second semiconductor element. The second semiconductor element has a planar size smaller than that of the first semiconductor element. The first semiconductor element and the second semiconductor element are arranged in a first direction. In the base member, a first groove is formed to surround the first semiconductor element, a second groove is formed to surround the second semiconductor element. The first groove and the second groove overlap each other in a region between the first semiconductor element and the second semiconductor element. In a second direction, a distance between portions of the second groove disposed to sandwich the second semiconductor element is smaller than a distance between portions of the first groove disposed to sandwich the first semiconductor element.

### CROSS REFERENCE TO RELATED APPLICATIONS

This nonprovisional application is based on Japanese Patent Application No. 2024-081897 filed on May 20, 2024 with the Japan Patent Office, the entire contents of which are hereby incorporated by reference.

### BACKGROUND OF THE INVENTION

### Field of the Invention

The present disclosure relates to a semiconductor device.

### Description of the Background Art

Conventionally, there has been known a semiconductor device in which a semiconductor element is bonded to a surface of a substrate by a bonding material such as solder (see, for example, Japanese Patent Laying-Open No. 2017-098508).

### SUMMARY OF THE INVENTION

In the semiconductor device disclosed in Japanese Patent Laying-Open No. 2017-098508, a plurality of grooves are formed in the surface of the substrate at positions facing corners of the semiconductor element, and the bonding material is filled into the grooves. In the semiconductor device described above, in order to fill the bonding material into the grooves, the bonding material is disposed to overflow from the grooves. As a result, when the bonding material is melted to fix the semiconductor element to the surface of the substrate, there is a possibility that the position of the semiconductor element may deviate and the amount of shift of the semiconductor element (that is, the amount of deviation from a position intended at the time of design) may increase.

When the amount of shift of the semiconductor element increases as described above, the position of a wire bonded to the semiconductor element may deviate and a short circuit may occur, or the step of bonding the wire to the semiconductor element may not be performed successfully, which means that assemblability of the semiconductor device is deteriorated. Furthermore, since independent grooves are individually formed for a plurality of semiconductor elements, there has been room for improvement in terms of downsizing of the semiconductor device.

Accordingly, an object of the present disclosure is to provide a semiconductor device that can suppress deterioration of assemblability and can achieve downsizing.

A semiconductor device according to the present disclosure includes a base member, a first semiconductor element, and a second semiconductor element. The base member is made of a conductive material. The first semiconductor element is connected to the base member by a bonding material. The second semiconductor element is connected to the base member by the bonding material. The second semiconductor element has a planar size smaller than that of the first semiconductor element. The first semiconductor element and the second semiconductor element are arranged in a first direction. In the base member, a first groove is formed to surround the first semiconductor element. In the base member, a second groove is formed to surround the second semiconductor element. The first groove and the second groove overlap each other in a region between the first semiconductor element and the second semiconductor element. In a second direction which is a direction orthogonal to the first direction, a distance between portions of the second groove disposed to sandwich the second semiconductor element is smaller than a distance between portions of the first groove disposed to sandwich the first semiconductor element.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic plan view of a semiconductor device according to a first embodiment.

FIG. 2 is a partially enlarged schematic plan view of the semiconductor device shown in FIG. 1.

FIG. 3 is a schematic cross sectional view taken along a line III-III in FIG. 2.

FIG. 4 is a schematic cross sectional view taken along a line IV-IV in FIG. 2.

FIG. 5 is a schematic cross sectional view of a first control wire of the semiconductor device shown in FIG. 1.

FIG. 6 is a schematic cross sectional view of a main current wire of the semiconductor device shown in FIG. 1.

FIG. 7 is a schematic partial cross sectional view showing a first variation of the semiconductor device shown in FIG. 1.

FIG. 8 is a schematic partial cross sectional view showing a second variation of the semiconductor device shown in FIG. 1.

FIG. 9 is a schematic partial cross sectional view showing a third variation of the semiconductor device shown in FIG. 1.

FIG. 10 is a schematic partial plan view showing a fourth variation of the semiconductor device shown in FIG. 1.

FIG. 11 is a schematic partial plan view showing a fifth variation of the semiconductor device shown in FIG. 1.

FIG. 12 is a schematic partial plan view showing a sixth variation of the semiconductor device shown in FIG. 1.

FIG. 13 is a partially enlarged schematic plan view of a semiconductor device according to a second embodiment.

### DESCRIPTION OF THE PREFERRED EMBODIMENTS

Hereinafter, embodiments of the present disclosure will be described. It should be noted that the same components will be designated by the same reference numerals, and the description thereof will not be repeated.

### First Embodiment

### <Configuration of Semiconductor Device>

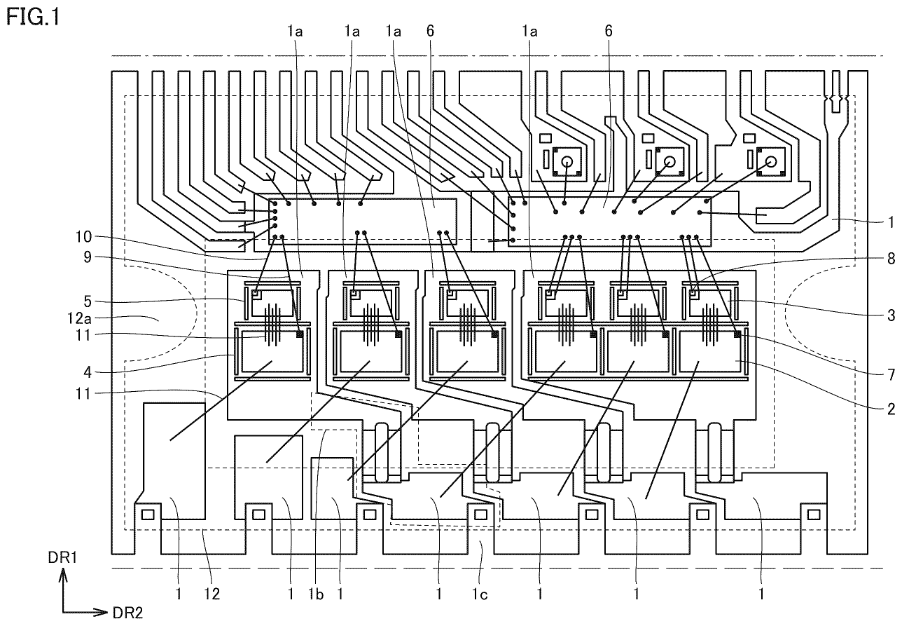

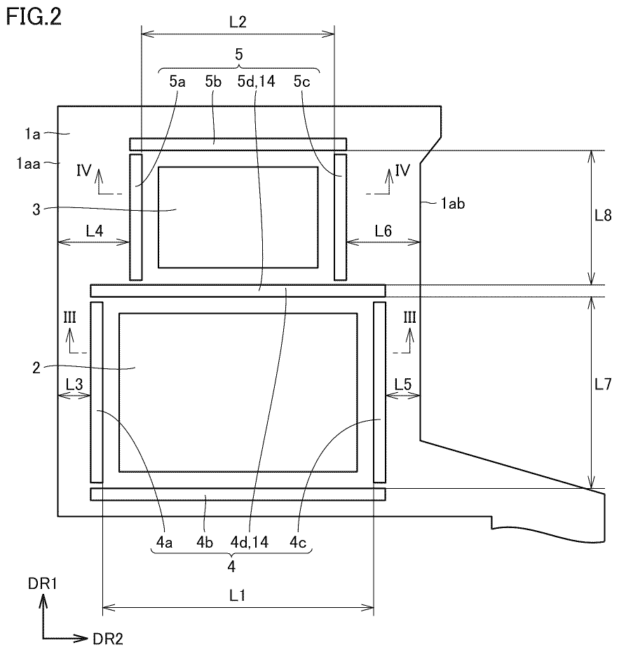

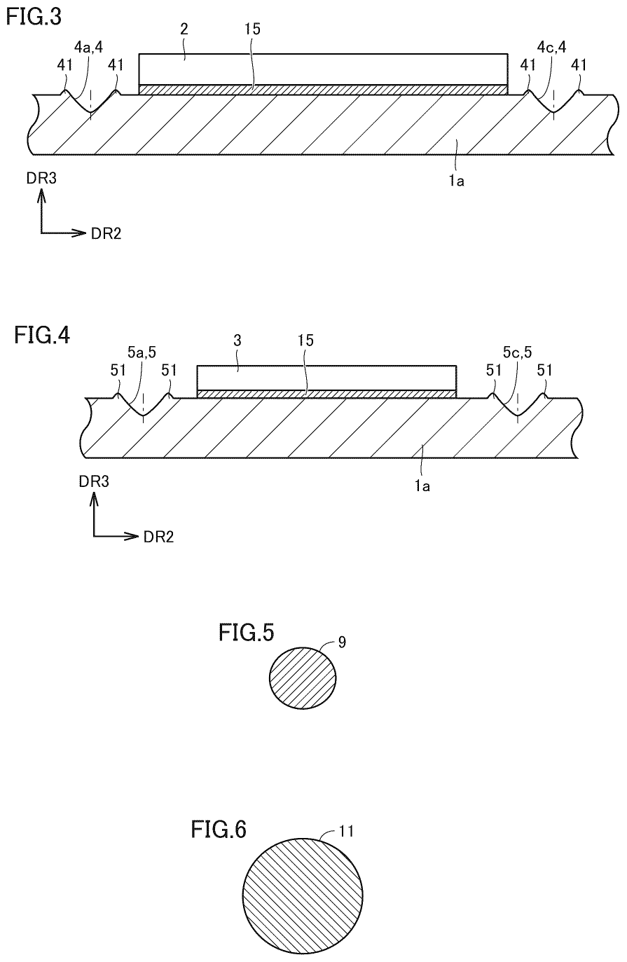

FIG. 1 is a schematic plan view of a semiconductor device according to a first embodiment of the present disclosure. FIG. 2 is a partially enlarged schematic plan view of the semiconductor device shown in FIG. 1. FIG. 3 is a schematic cross sectional view taken along a line III-III in FIG. 2. FIG. 4 is a schematic cross sectional view taken along a line IV-IV in FIG. 2. FIG. 5 is a schematic cross sectional view of a first control wire of the semiconductor device shown in FIG. 1. FIG. 6 is a schematic cross sectional view of a main current wire of the semiconductor device shown in FIG. 1.

As shown in FIGS. 1 to 6, the semiconductor device according to the present disclosure mainly includes a lead frame 1, a first semiconductor element 2, a second semiconductor element 3, a third semiconductor element 6, a first control wire 9, a second control wire 10, a main current wire 11, and a resin 12. Lead frame 1 mainly includes a base member 1a, a connection portion 1b, and a terminal 1c. As shown in FIG. 1, base member 1a is disposed at a substantially central portion of lead frame 1. Terminal 1c is disposed at an outer peripheral portion of lead frame 1. Base member 1a and terminal 1c are connected by connection portion 1b. Connection portion 1b is made of a metal member integral with base member 1a. Connection portion 1b is electrically connected with terminal 1c. Base member 1a, connection portion 1b, and terminal 1c are made of a conductive material.

First semiconductor element 2 is connected to base member 1a by a bonding material 15. Second semiconductor element 3 is connected to a region adjacent to first semiconductor element 2 in base member 1a by bonding material 15. As bonding material 15, solder can be used, for example. Second semiconductor element 3 has a planar size smaller than that of first semiconductor element 2. First semiconductor element 2 and second semiconductor element 3 are arranged in a first direction DR1.

In the semiconductor device shown in FIG. 1, four base members 1a are disposed at a central portion of lead frame 1. Four base members 1a are arranged along a second direction DR2 perpendicular to first direction DR1. First semiconductor element 2 and second semiconductor element 3 are connected to each of three base members 1a of four base members 1a. The other one base member 1a has a size larger than that of each of three base members 1a. Three first semiconductor elements 2 and three second semiconductor elements 3 are connected to the other one base member 1a. That is, in the semiconductor device shown in FIG. 1, six first semiconductor elements 2 and six second semiconductor elements 3 are connected to base members 1a.

Third semiconductor element 6 is connected to another region in lead frame 1 adjacent to base member 1a. In the semiconductor device shown in FIG. 1, two third semiconductor elements 6 are connected to lead frame 1. When viewed from second semiconductor element 3, third semiconductor element 6 is located opposite to first semiconductor element 2.

First semiconductor element 2 is a silicon-based insulated gate bipoloar transistor (IGBT), for example. Second semiconductor element 3 is a silicon carbide (SiC)-based metal-oxide-semiconductor field-effect transistor (MOSFET), for example. Third semiconductor element 6 is a driver integrated circuit (IC), for example. It should be noted that first semiconductor element 2, second semiconductor element 3, and third semiconductor element 6 may be any type of semiconductor element other than those described above. For example, as a semiconductor material constituting second semiconductor element 3, silicon (Si) may be used, or a compound semiconductor material such as gallium nitride (GaN) or gallium oxide (Ga₂O₃) may be used.

Third semiconductor element 6 controls first semiconductor element 2 and second semiconductor element 3. It should be noted that third semiconductor element 6 may control one of first semiconductor element 2 and second semiconductor element 3. The planar size of second semiconductor element 3 is smaller than the planar size of first semiconductor element 2.

In base member 1a, a first groove 4 is formed to surround each first semiconductor element 2. As shown in FIG. 2, first groove 4 is constituted by a plurality of independent groove portions. Specifically, first groove 4 includes first groove portions 4a, 4b, 4c, and 4d. Each of first groove portions 4a, 4b, 4c, and 4d is a linear groove. Each of four first groove portions 4a, 4b, 4c, and 4d is disposed to face one outer peripheral side of first semiconductor element 2 having a quadrangular planar shape. First groove portions 4a, 4b, 4c, and 4d are disposed to be spaced from each other. First groove portions 4a, 4b, 4c, and 4d are disposed to form a quadrangular planar shape. First groove portions 4a and 4c are formed to extend along first direction DR1. First groove portions 4b and 4d are formed to extend along second direction DR2 perpendicular to first direction DR1.

It should be noted that, when a plurality of first semiconductor elements 2 are arranged as shown in FIG. 1, a plurality of first grooves 4 surrounding these first semiconductor elements 2 may share a part of the first groove portions constituting each first groove 4. For example, when the plurality of first semiconductor elements 2 are arranged along second direction DR2 as shown in FIG. 1, first grooves 4 surrounding the plurality of first semiconductor elements 2 may share first groove portions 4b and 4d extending along second direction DR2. It should be noted that, in FIG. 1, one first groove portion 4b (see FIG. 2) and one first groove portion 4d (see FIG. 2) are disposed adjacent to three first semiconductor elements 2, and thereby are used in common in three first grooves 4.

Further, the first groove portions (first groove portions 4a and 4c in FIG. 2) located between the plurality of first semiconductor elements 2 arranged along second direction DR2 as shown in FIG. 1 may also be shared in the plurality of first grooves 4 surrounding the plurality of first semiconductor elements 2. That is, one first groove portion may be formed as a common groove portion, between first semiconductor elements 2 arranged along second direction DR2. In this case, the one first groove portion functions as first groove portion 4a and first groove portion 4c in two adjacent first grooves 4.

As shown in FIG. 3, a cross sectional shape of first groove 4 in a cross section perpendicular to a direction in which first groove 4 extends is a V-shape. On a surface of base member 1a, a protrusion 41 is formed at a position along an outer edge of first groove 4. Protrusion 41 protrudes from the surface of base member 1a. From a different viewpoint, protrusion 41 protrudes from the surface of base member 1a along a third direction DR3 perpendicular to first direction DR1 and second direction DR2. A surface of protrusion 41 is contiguous to an inner peripheral surface of first groove 4.

As shown in FIGS. 1 and 2, in base member 1a, a second groove 5 is formed to surround each second semiconductor element 3. As shown in FIG. 2, second groove 5 is constituted by a plurality of independent groove portions. Specifically, second groove 5 includes four second groove portions 5a, 5b, 5c, and 5d. Each of second groove portions 5a, 5b, 5c, and 5d is a linear groove. Each of four second groove portions 5a, 5b, 5c, and 5d is disposed to face one outer peripheral side of second semiconductor element 3 having a quadrangular planar shape. Second groove portions 5a, 5b, 5c, and 5d are disposed to be spaced from each other. Second groove portions 5a, 5b, 5c, and 5d are disposed such that second groove 5 has a quadrangular planar shape. Second groove portions 5a and 5c are formed to extend along first direction DR1. Second groove portions 5b and 5d are formed to extend along second direction DR2.

As shown in FIG. 4, a cross sectional shape of second groove 5 in a cross section perpendicular to a direction in which second groove 5 extends is a V-shape. On the surface of base member 1a, a protrusion 51 is formed at a position along an outer edge of second groove 5. Protrusion 51 protrudes from the surface of base member 1a. A surface of protrusion 51 is contiguous to an inner peripheral surface of second groove 5.

As shown in FIGS. 1 and 2, first groove 4 and second groove 5 overlap each other in a region between first semiconductor element 2 and second semiconductor element 3. That is, first groove portion 4d and second groove portion 5d serve as a common groove portion 14 as the same groove. It should be noted that, since the size of second groove 5 is smaller than the size of first groove 4, end portions of second groove portions 5a and 5c are disposed to face regions located more inward than end portions of common groove portion 14.

As shown in FIG. 2, the sizes of first groove 4 and second groove 5 are determined corresponding to the sizes of first semiconductor element 2 and second semiconductor element 3. Specifically, in second direction DR2 which is a direction orthogonal to first direction DR1, a distance L2 between second groove portions 5a and 5c disposed to sandwich second semiconductor element 3 is smaller than a distance L1 between first groove portions 4a and 4c disposed to sandwich first semiconductor element 2. This corresponds to the width of second semiconductor element 3 being narrower than the width of first semiconductor element 2 in second direction DR2. From a different viewpoint, in second direction DR2, distances L4 and L6 between end portions 1aa and 1ab of base member 1a and second groove 5 are larger than distances L3 and L5 between end portions 1aa and 1ab of base member 1a and first groove 4. That is, second groove 5 is disposed at a position more distant from end portions 1aa and 1ab of base member 1a (closer to the center of base member 1a in second direction DR2) than first groove 4.

Further, in first direction DR1, a distance L8 between second groove portions 5b and 5d disposed to sandwich second semiconductor element 3 is smaller than a distance L7 between first groove portions 4b and 4d disposed to sandwich first semiconductor element 2. This corresponds to the width of second semiconductor element 3 being narrower than the width of first semiconductor element 2 in first direction DR1.

As shown in FIG. 1, a first gate pad 7 is formed on an upper surface of first semiconductor element 2. A second gate pad 8 is formed on an upper surface of second semiconductor element 3. Third semiconductor element 6 and first gate pad 7 of first semiconductor element 2 are electrically connected by first control wire 9. Third semiconductor element 6 and second gate pad 8 of second semiconductor element 3 are electrically connected by second control wire 10. First semiconductor element 2 and second semiconductor element 3 are electrically connected by main current wire 11. Further, first semiconductor element 2 and lead frame 1 are electrically connected by main current wire 11. In a direction in which second control wire 10 extends, second semiconductor element 3 is disposed to be sandwiched between first semiconductor element 2 and third semiconductor element 6.

As shown in FIGS. 5 and 6, a cross sectional area of first control wire 9 as a control wire is smaller than a cross sectional area of main current wire 11. A cross sectional area of second control wire 10 is equal to the cross sectional area of first control wire 9. Accordingly, the cross sectional area of second control wire 10 is smaller than the cross sectional area of main current wire 11.

As shown in FIG. 1, resin 12 covers a part of terminal 1c and base member 1a and connection portion 1b in lead frame 1, first semiconductor element 2, second semiconductor element 3, third semiconductor element 6, first control wire 9, second control wire 10, and main current wire 11. It should be noted that screw hole portions 12a for fixing the semiconductor device are formed in resin 12. Screw hole portions 12a are disposed at positions sandwiching base member 1a in second direction DR2. Resin 12 is an insulating resin. An end portion of terminal 1c protrudes from resin 12. Terminal 1c is used to perform electrical connection with the outside of the semiconductor device.

As shown in FIG. 1, in first direction DR1, a distance from connection portion 1b to second groove 5 is larger than a distance from connection portion 1b to first groove 4. That is, in first direction DR1, when viewed from first groove 4 and first semiconductor element 2, second groove 5 and second semiconductor element 3 are disposed opposite to connection portion 1b.

Further, in first direction DR1, a distance from third semiconductor element 6 to second groove 5 is smaller than a distance from third semiconductor element 6 to first groove 4. That is, in first direction DR1, when viewed from second groove 5 and second semiconductor element 3, third semiconductor element 6 is disposed opposite to first groove 4 and first semiconductor element 2.

### <Function>

The semiconductor device according to the present disclosure includes base member 1a, first semiconductor element 2, and second semiconductor element 3. Base member 1a is made of a conductive material. First semiconductor element 2 is connected to base member 1a by bonding material 15. Second semiconductor element 3 is connected to base member 1a by bonding material 15. Second semiconductor element 3 has a planar size smaller than that of first semiconductor element 2. First semiconductor element 2 and second semiconductor element 3 are arranged in first direction DR1. In base member 1a, first groove 4 is formed to surround first semiconductor element 2. In base member 1a, second groove 5 is formed to surround second semiconductor element 3. First groove 4 and second groove 5 overlap each other in the region between first semiconductor element 2 and second semiconductor element 3. In second direction DR2 which is a direction orthogonal to first direction DR1, distance L2 between portions (second groove portions 5a and 5c) of second groove 5 disposed to sandwich second semiconductor element 3 is smaller than distance L1 between portions (first groove portions 4a and 4c) of first groove 4 disposed to sandwich first semiconductor element 2.

According to such a configuration, first groove 4 and second groove 5 are formed to have sizes corresponding to the planar sizes of first semiconductor element 2 and second semiconductor element 3. Thus, when first semiconductor element 2 and second semiconductor element 3 are fixed to base member 1a via bonding material 15, it is possible to prevent melted bonding material 15 from spreading more outward than first groove 4 or second groove 5. Accordingly, it is possible to suppress excessive deviation of the positions of first semiconductor element 2 and second semiconductor element 3 from designed positions. Therefore, when connection of wires to first semiconductor element 2 and second semiconductor element 3 is performed, it is possible to suppress occurrence of a problem that the position of connecting a wire deviates from a designed position and the wires come into contact with each other. That is, the connection of the wires to first semiconductor element 2 and second semiconductor element 3 can be performed reliably and with high accuracy, and thereby deterioration of assemblability of the semiconductor device can be suppressed.

Further, since protrusions 41 and 51 are formed adjacent to first groove 4 and second groove 5 as shown in FIGS. 3 and 4, a flow of melted bonding material 15 is also hindered by protrusions 41 and 51. That is, protrusions 41 and 51 also contribute to the effect of suppressing bonding material 15 from spreading to the outside of first groove 4 or second groove 5.

Furthermore, first groove portion 4d as a part of first groove 4 and second groove portion 5d as a part of second groove 5 overlap each other to form common groove portion 14. Since first groove portion 4d and second groove portion 5d are shared in this manner, the total occupied area of first groove 4 and second groove 5 can be reduced when compared with a case where first groove 4 and second groove 5 are formed independently of each other (a case where first groove portion 4d and second groove portion 5d are independently formed). Accordingly, the semiconductor device can be downsized. Further, since the area occupied by the grooves can be reduced when compared with the case where first groove 4 and second groove 5 are independently formed, it is possible to suppress a decrease in the strength of base member 1a due to formation of first groove 4 and second groove 5.

Furthermore, since only one groove portion is formed as common groove portion 14 between first semiconductor element 2 and second semiconductor element 3, the distance between first semiconductor element 2 and second semiconductor element 3 in first direction DR1 can be reduced when compared with a case where first groove portion 4d and second groove portion 5d are respectively formed as described above. Here, a case where third semiconductor element 6 is disposed opposite to first semiconductor element 2 when viewed from second semiconductor element 3 as shown in FIG. 1 will be considered, for example. The distance between third semiconductor element 6 and first semiconductor element 2 in the semiconductor device shown in FIG. 1 is shorter than that in the case where first groove portion 4d and second groove portion 5d are respectively independently formed as described above. Accordingly, the length of the wire (first control wire 9) connecting third semiconductor element 6 and first semiconductor element 2 can be designed to be relatively short. As a result, when resin 12 is molded, it is possible to suppress occurrence of a problem that the wire is deformed by resin 12 injected into a mold. As a result, product assemblability of the semiconductor device can be improved.

The semiconductor device described above includes terminal 1c, connection portion 1b, and resin 12. Connection portion 1b electrically connects terminal 1c and base member 1a. Resin 12 covers base member 1a and connection portion 1b. Resin 12 is an insulating resin. Terminal 1c protrudes from resin 12. In first direction DR1, the distance from connection portion 1b to second groove 5 is larger than the distance from connection portion 1b to first groove 4.

Here, in the process of manufacturing the semiconductor device, for example, there is a case where a wire such as first control wire 9 or second control wire 10 is connected to first semiconductor element 2 or second semiconductor element 3 using ultrasonic waves or the like. In this case, it is necessary to position and fix base member 1a. Accordingly, base member 1a is locally pressed by a pressing member such as a jig to fix base member 1a. In this case, if base member 1a is pressed at a position as distant from connection portion 1b as possible, positioning of base member 1a can be easily and stably performed. Therefore, by disposing second groove 5 with a smaller size at a position relatively distant from connection portion 1b as described above, it is possible to easily secure a region for bringing the pressing member into contact with the surface of base member 1a around second groove 5 (that is, a surface portion relatively distant from connection portion 1b). As a result, the positioning of base member 1a can be easily performed.

In the semiconductor device described above, base member 1a and connection portion 1b are made of an integral metal member.

In this case, the number of components of the semiconductor device can be reduced when compared with a case where base member 1a and connection portion 1b are prepared as separate components. Further, since there is no need to perform the step of connecting base member 1a and connection portion 1b which are separate bodies, the number of manufacturing steps can be reduced when compared with the case where base member 1a and connection portion 1b are separate bodies.

In the semiconductor device described above, in second direction DR2, distances L4 and L6 between end portions 1aa and 1ab of base member 1a and second groove 5 are larger than distances L3 and L5 between end portions 1aa and 1ab of base member 1a and first groove 4.

Here, when a wire is connected to first semiconductor element 2 or second semiconductor element 3 by wire bonding or the like, base member 1a is pressed by a pressing member such as a jig and fixed, and then the step of connecting the wire is performed. On this occasion, it is preferable to press base member 1a at two positions sandwiching first semiconductor element 2 or second semiconductor element 3. In the above configuration, distances L4 and L6 between end portions 1aa and 1ab of base member 1a and portions (second groove portions 5a and 5c in FIG. 2) of second groove at positions sandwiching second semiconductor element 3 in second direction DR2 are relatively large. Accordingly, base member 1a can be easily pressed by the pressing member and fixed at positions sandwiching second groove 5 in second direction DR2. As a result, the step of connecting the wire can be reliably and accurately performed.

In the semiconductor device described above, the cross sectional shapes of first groove 4 and second groove 5 are a V-shape. In this case, first groove 4 and second groove 5 can be easily formed by pressing a die or the like having a V-shaped cross sectional shape against the surface of base member 1a, and plastically working the surface of base member 1a.

The semiconductor device described above includes third semiconductor element 6. Third semiconductor element 6 controls at least one of first semiconductor element 2 and second semiconductor element 3. In first direction DR1, the distance from third semiconductor element 6 to second groove 5 is smaller than the distance from third semiconductor element 6 to first groove 4. In first direction DR1, distance L8 between portions (second groove portions 5b and 5d) of second groove 5 disposed to sandwich second semiconductor element 3 is smaller than distance L7 between portions (first groove portions 4b and 4d) of first groove 4 disposed to sandwich first semiconductor element 2.

In this case, the total length of the wires (first control wire 9 and second control wire 10) connecting third semiconductor element 6 to first semiconductor element 2 and second semiconductor element 3 can be shortened when compared with a case where first semiconductor element 2 and first groove 4 having larger sizes are disposed at positions relatively close to third semiconductor element 6 in first direction DR1.

The semiconductor device described above includes main current wire 11, and first control wire 9 and second control wire 10 as control wires. Third semiconductor element 6 controls at least one of first semiconductor element 2 and the second semiconductor element 3. Main current wire 11 electrically connects first semiconductor element 2 and second semiconductor element 3. First control wire 9 or second control wire 10 as a control wire electrically connects one of first semiconductor element 2 and second semiconductor element 3 to third semiconductor element 6. The cross sectional area of first control wire 9 or second control wire 10 as the control wire is smaller than the cross sectional area of main current wire 11.

In this case, first control wire 9 and second control wire 10 having a relatively small cross sectional area are more likely to deform than main current wire 11. Accordingly, it is particularly effective from the viewpoint of suppressing deformation of first control wire 9 and second control wire 10 to dispose second semiconductor element 3 and second groove 5 having smaller sizes at positions relatively close to third semiconductor element 6 in first direction DR1 as described above, and thereby shorten the total length of first control wire 9 and second control wire 10.

### <Configurations and Functions of Variations>

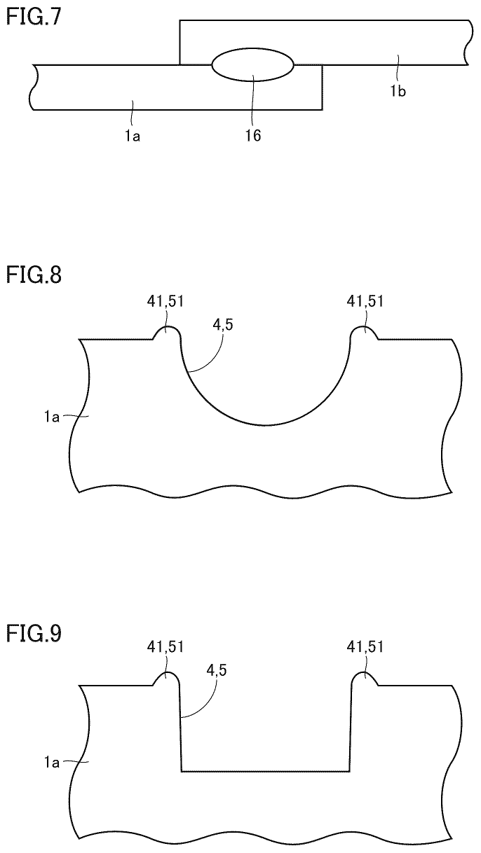

FIG. 7 is a schematic partial cross sectional view showing a first variation of the semiconductor device shown in FIG. 1. FIG. 7 shows a cross section of a bonding portion between base member 1a and connection portion 1b. The semiconductor device shown in FIG. 7 basically has the same configuration and can achieve the same effect as those of the semiconductor device shown in FIGS. 1 to 6, but is different from the semiconductor device shown in FIGS. 1 to 6 in that base member 1a and connection portion 1b which are separate bodies are connected in lead frame 1 (see FIG. 1).

In the semiconductor device shown in FIG. 7, base member 1a and connection portion 1b are separate bodies. Base member 1a and connection portion 1b are bonded via an alloy layer 16. That is, base member 1a and connection portion 1b are ultrasonically bonded. It should be noted that base member 1a and connection portion 1b may be connected via solder.

In this case, since base member 1a and connection portion 1b are separate bodies, thicknesses of and materials for base member 1a and connection portion 1b can be individually selected. Accordingly, the degree of freedom of design of the semiconductor device can be increased.

FIG. 8 is a schematic partial cross sectional view showing a second variation of the semiconductor device shown in FIG. 1. FIG. 8 shows cross sectional shapes of first groove 4 and second groove 5. The semiconductor device shown in FIG. 8 basically has the same configuration and can achieve the same effect as those of the semiconductor device shown in FIGS. 1 to 6, but the cross sectional shapes of first groove 4 and second groove 5 are different from those in the semiconductor device shown in FIGS. 1 to 6.

In the semiconductor device shown in FIG. 8, the cross sectional shapes of first groove 4 and second groove 5 are a semicircular shape. Even in such a configuration, melted bonding material 15 can be trapped in first groove 4 and second groove 5, as in the semiconductor device shown in FIGS. 1 to 6. Accordingly, it is possible to suppress bonding material 15 from spreading to the outside of first groove 4 and second groove 5. Further, first groove 4 and second groove 5 can be easily formed by pressing a die or the like having a semicircular cross sectional shape against the surface of base member 1a, and plastically working the surface of base member 1a.

FIG. 9 is a schematic partial cross sectional view showing a third variation of the semiconductor device shown in FIG. 1. FIG. 9 shows cross sectional shapes of first groove 4 and second groove 5, as in FIG. 8. The semiconductor device shown in FIG. 9 basically has the same configuration and can achieve the same effect as those of the semiconductor device shown in FIGS. 1 to 6, but the cross sectional shapes of first groove 4 and second groove 5 are different from those in the semiconductor device shown in FIGS. 1 to 6.

In the semiconductor device shown in FIG. 9, the cross sectional shapes of first groove 4 and second groove 5 are a rectangular shape. Even in such a configuration, melted bonding material 15 can be trapped in first groove 4 and second groove 5, as in the semiconductor device shown in FIGS. 1 to 6. Accordingly, it is possible to suppress bonding material 15 from spreading to the outside of first groove 4 and second groove 5. Further, first groove 4 and second groove 5 can be easily formed by pressing a die or the like having a rectangular cross sectional shape against the surface of base member 1a, and plastically working the surface of base member 1a. It should be noted that the cross sectional shapes of first groove 4 and second groove 5 may be any shape other than the semicircular shape and the rectangular shape described above, such as a U-shape or a polygonal shape.

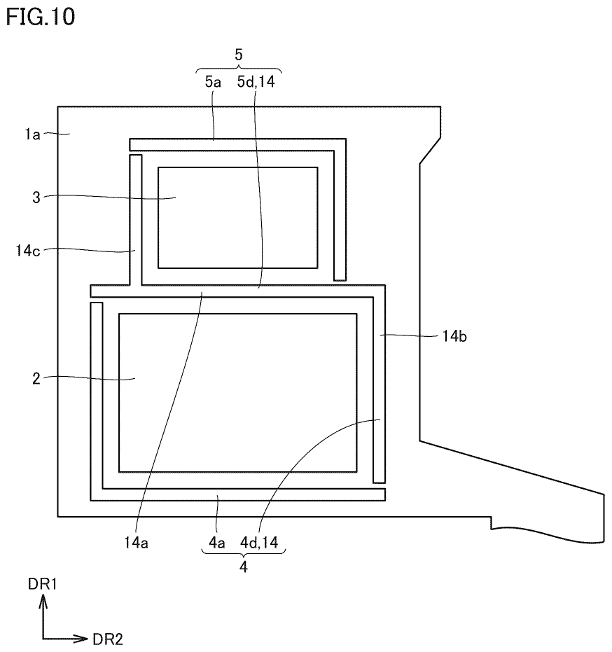

FIG. 10 is a schematic partial plan view showing a fourth variation of the semiconductor device shown in FIG. 1. FIG. 10 corresponds to FIG. 2. The semiconductor device shown in FIG. 10 basically has the same configuration and can achieve the same effect as those of the semiconductor device shown in FIGS. 1 to 6, but the planar shapes of first groove 4 and second groove 5 are different from those in the semiconductor device shown in FIGS. 1 to 6.

In the semiconductor device shown in FIG. 10, first groove 4 is constituted by two first groove portions 4a and 4d. Two first groove portions 4a and 4d are disposed to be spaced from each other. First groove portion 4a is a groove having an L-shaped planar shape. First groove portion 4d is formed such that linear portions 14a, 14b, and 14c are contiguous. Portions 14a and 14b are connected to form an L-shaped planar shape. Portion 14a is disposed between first semiconductor element 2 and second semiconductor element 3. Portion 14b is contiguous to an end portion of portion 14a and extends along first direction DR1. An end portion of portion 14a and an end portion of portion 14b located opposite to a connection portion between portion 14a and portion 14b are disposed at positions facing end portions of first groove portion 4a. First groove portion 4a and portions 14a and 14b in first groove portion 4d as common groove portion 14 are disposed to face outer peripheral sides of first semiconductor element 2.

In the semiconductor device shown in FIG. 10, second groove 5 is constituted by two second groove portions 5a and 5d. Two second groove portions 5a and 5d are disposed to be spaced from each other. Second groove portion 5a is a groove having an L-shaped planar shape. Second groove portion 5d serves as common groove portion 14 in which portions 14a, 14b, and 14c are contiguous. Portion 14c is connected to a position distant from the end portion of portion 14a (the end portion opposite to an end portion connected to portion 14b). Portion 14c extends along first direction DR1. A portion of portion 14a distant from the connection portion between portion 14a and portion 14b and an end portion of portion 14c (an end portion opposite to an end portion connected to portion 14a) are disposed at positions facing end portions of second groove portion 5a. Second groove portion 5a and portions 14a and 14c in second groove portion 5d as common groove portion 14 are disposed to face outer peripheral sides of second semiconductor element 3.

By using first groove 4 and second groove 5 configured as described above, melted bonding material 15 can also be trapped in first groove 4 and second groove 5. Accordingly, it is possible to suppress bonding material 15 from spreading to the outside of first groove 4 and second groove 5.

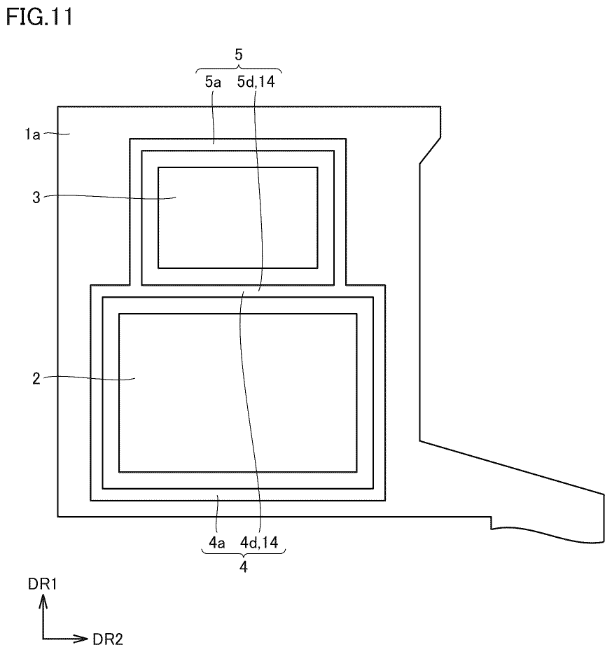

FIG. 11 is a schematic partial plan view showing a fifth variation of the semiconductor device shown in FIG. 1. FIG. 11 corresponds to FIG. 2. The semiconductor device shown in FIG. 11 basically has the same configuration and can achieve the same effect as those of the semiconductor device shown in FIGS. 1 to 6, but the planar shapes of first groove 4 and second groove 5 are different from those in the semiconductor device shown in FIGS. 1 to 6.

In the semiconductor device shown in FIG. 11, first groove 4 is one annular groove. First groove 4 is constituted by first groove portions 4a and 4d which are contiguous to each other. The planar shape of first groove portion 4a is a U-shape constituted by linear portions. The planar shape of first groove portion 4d is a linear shape. First groove portion 4d serves as common groove portion 14. First groove portion 4d is disposed between first semiconductor element 2 and second semiconductor element 3. End portions of first groove portion 4a are connected to end portions of first groove portion 4d. First groove 4 is an annular groove having a rectangular planar shape.

In the semiconductor device shown in FIG. 11, second groove 5 is one annular groove. Second groove 5 is constituted by second groove portions 5a and 5d. The planar shape of second groove portion 5a is a U-shape constituted by linear portions. The planar shape of second groove portion 5d is a linear shape. Second groove portion 5d serves as common groove portion 14. Second groove portion 5d is the same groove as first groove portion 4d. End portions of second groove portion 5a are connected to portions distant from end portions of second groove portion 5d. Second groove 5 is an annular groove having a rectangular planar shape.

By using first groove 4 and second groove 5 configured as described above, melted bonding material 15 can also be trapped in first groove 4 and second groove 5. Accordingly, it is possible to suppress bonding material 15 from spreading to the outside of first groove 4 and second groove 5.

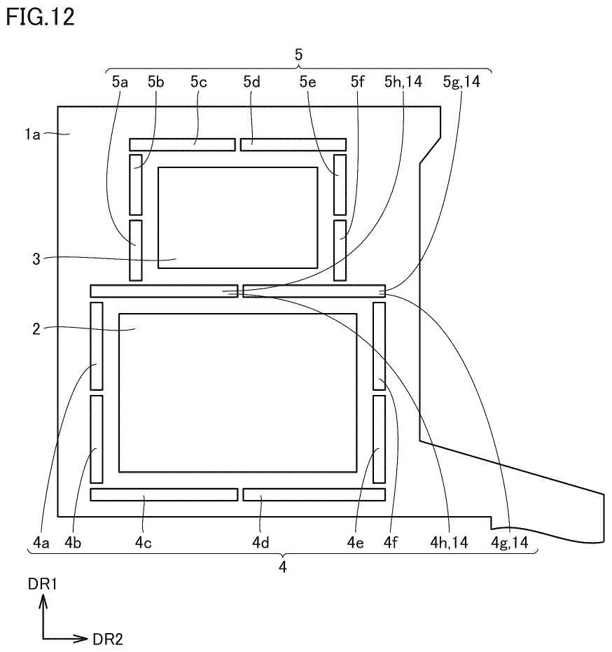

FIG. 12 is a schematic partial plan view showing a sixth variation of the semiconductor device shown in FIG. 1. FIG. 12 corresponds to FIG. 2. The semiconductor device shown in FIG. 12 basically has the same configuration and can achieve the same effect as those of the semiconductor device shown in FIGS. 1 to 6, but the planar shapes of first groove 4 and second groove 5 are different from those in the semiconductor device shown in FIGS. 1 to 6.

In the semiconductor device shown in FIG. 12, a plurality of first groove portions are disposed for one outer peripheral side of first semiconductor element 2. Specifically, first groove 4 is constituted by eight first groove portions 4a, 4b, 4c, 4d, 4e, 4f, 4g and 4h which are linear grooves. Eight first groove portions 4a, 4b, 4c, 4d, 4e, 4f, 4g and 4h are disposed to be spaced from each other. First groove portions 4a and 4b are linearly arranged along first direction DR1. First groove portions 4a and 4b are disposed to face one of the outer peripheral sides of first semiconductor element 2. First groove portions 4c and 4d are linearly arranged along second direction DR2. An end portion of first groove portion 4b and an end portion of first groove portion 4c are disposed to face each other with a spacing therebetween. First groove portions 4c and 4d are disposed to face another one of the outer peripheral sides of first semiconductor element 2.

First groove portions 4e and 4f are linearly arranged along first direction DR1. When viewed from first semiconductor element 2, first groove portions 4e and 4f are disposed opposite to first groove portions 4a and 4b. An end portion of first groove portion 4d and an end portion of first groove portion 4e are disposed to face each other with a spacing therebetween. First groove portions 4e and 4f are disposed to face still another one of the outer peripheral sides of first semiconductor element 2.

First groove portions 4g and 4h are arranged linearly along second direction DR2. First groove portions 4g and 4h serve as common groove portion 14. First groove portions 4g and 4h are disposed between first semiconductor element 2 and second semiconductor element 3. An end portion of first groove portion 4g (an end portion opposite to an inner end portion facing first groove portion 4h, in first groove portion 4g) faces an end portion of first groove portion 4f. An end portion of first groove portion 4h (an end portion opposite to an inner end portion facing first groove portion 4g, in first groove portion 4h) faces an end portion of first groove portion 4a. First groove portions 4a, 4b, 4c, 4d, 4e, 4f, 4g and 4h are disposed to face the outer peripheral sides of first semiconductor element 2.

In the semiconductor device shown in FIG. 12, a plurality of second groove portions are disposed for one outer peripheral side of second semiconductor element 3. Specifically, second groove 5 is constituted by eight second groove portions 5a, 5b, 5c, 5d, 5e, 5f, 5g and 5h which are linear grooves. Eight second groove portions 5a, 5b, 5c, 5d, 5e, 5f, 5g and 5h are disposed to be spaced from each other. Second groove portions 5a and 5b are linearly arranged along first direction DR1. Second groove portions 5a and 5b are disposed to face one of the outer peripheral sides of second semiconductor element 3. Second groove portions 5c and 5d are linearly arranged along second direction DR2. An end portion of second groove portion 5b and an end portion of second groove portion 5c are disposed to face each other with a spacing therebetween. Second groove portions 5c and 5d are disposed to face another one of the outer peripheral sides of second semiconductor element 3.

Second groove portions 5e and 5f are linearly arranged along first direction DR1. When viewed from second semiconductor element 3, second groove portions 5e and 5f are disposed opposite to second groove portions 5a and 5b. An end portion of second groove portion 5d and an end portion of second groove portion 5e are disposed to face each other with a spacing therebetween. Second groove portions 5e and 5f are disposed to face still another one of the outer peripheral sides of second semiconductor element 3.

Second groove portions 5g and 5h are arranged linearly along second direction DR2. Second groove portions 5g and 5h serve as common groove portion 14. Second groove portions 5g and 5h are disposed between first semiconductor element 2 and second semiconductor element 3. A region distant from an end portion of second groove portion 5g (an end portion opposite to an inner end portion facing second groove portion 5h, in second groove portion 5g) faces an end portion of second groove portion 5f. A region distant from an end portion of second groove portion 5h (an end portion opposite to an inner end portion facing second groove portion 5g, in second groove portion 5h) faces an end portion of second groove portion 5a. Second groove portions 5a, 5b, 5c, 5d, 5e, 5f, 5g and 5h are disposed to face the outer peripheral sides of second semiconductor element 3.

By using first groove 4 and second groove 5 configured as described above, melted bonding material 15 can also be trapped in first groove 4 and second groove 5. Accordingly, it is possible to suppress bonding material 15 from spreading to the outside of first groove 4 and second groove 5.

### Second Embodiment

### <Configuration of Semiconductor Device>

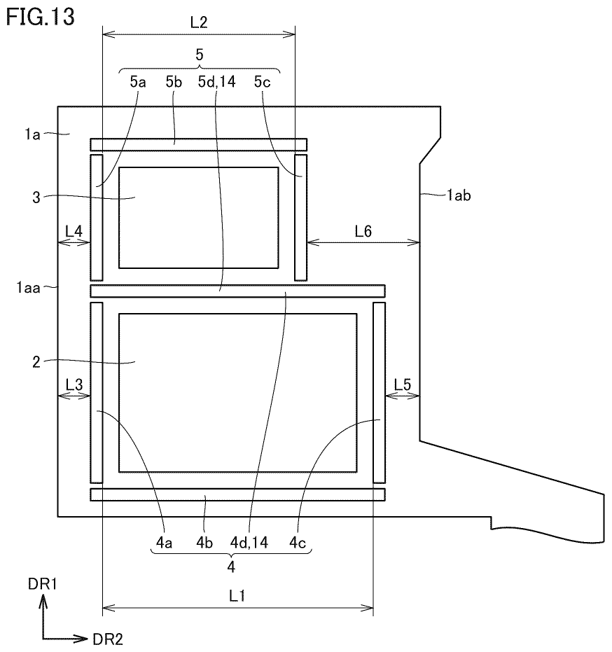

FIG. 13 is a partially enlarged schematic plan view of a semiconductor device according to a second embodiment. FIG. 13 corresponds to FIG. 2. The semiconductor device shown in FIG. 13 basically has the same configuration and can achieve the same effect as those of the semiconductor device shown in FIGS. 1 to 6, but the relative positional relation between first groove 4/first semiconductor element 2 and second groove 5/second semiconductor element 3 is different from that in the semiconductor device shown in FIGS. 1 to 6.

In the semiconductor device shown in FIG. 13, the position of the center of second groove 5 and second semiconductor element 3 in second direction DR2 deviates from the position of the center of first groove 4 and first semiconductor element 2 in second direction DR2. Specifically, first groove portion 4a and second groove portion 5a are located at the same position in second direction DR2. Further, an outer peripheral side of first semiconductor element 2 facing first groove portion 4a and an outer peripheral side of second semiconductor element 3 facing second groove portion 5a are located at the same position in second direction DR2.

Accordingly, in second direction DR2, distance L4 between end portion 1aa of base member 1a and second groove 5 is substantially equal to distance L3 between end portion 1aa of base member 1a and first groove 4. On the other hand, distance L6 between end portion 1ab of base member 1a and second groove 5 is larger than distance L5 between end portion 1ab of base member 1a and first groove 4. Further, as shown in FIG. 13, distance L6 is different from distance L4. Specifically, distance L6 is larger than distance L4. Accordingly, the area of a region in base member 1a located to the right of second groove 5 in second direction DR2 is larger than the area of a region in base member 1a located to the left of second groove 5.

### <Function>

In the semiconductor device described above, in second direction DR2, distance L4 between one end portion 1aa of base member 1a and second groove 5 is different from distance L6 between the other end portion 1ab of base member 1a and second groove 5.

Here, when a wire is connected to first semiconductor element 2 or second semiconductor element 3 by wire bonding or the like, base member 1a may be pressed by a pressing member such as a jig and fixed, and then the step of connecting the wire may be performed. On this occasion, there is a case where, depending on the conditions such as the shape of base member 1a, base member 1a may be pressed at one position. Further, there is also a case where, for example, there is a sufficient space between one of two end portions 1aa and 1ab of base member 1a and second groove 5, and there may be no problem even if second groove 5 is brought close to the other of two end portions 1aa and 1ab of base member 1a.

In the above configuration, one of two regions outside the portions of second groove 5 at positions sandwiching second semiconductor element 3 in second direction DR2 has a relatively large area. Accordingly, base member 1a can be pressed by the pressing member and fixed in the region having the large area (for example, the region located to the right of second groove 5 in FIG. 13). As a result, the degree of freedom of design of the semiconductor device can be increased when compared with a case where spaces for pressing base member 1a by the pressing member are secured in two regions sandwiching second semiconductor element 3.

It should be understood that the embodiments disclosed herein are illustrative and non-restrictive in every respect. At least two of the embodiments disclosed herein may be combined as long as there is no contradiction. The basic scope of the present disclosure is defined by the scope of the claims, rather than the description above, and is intended to include any modifications within the scope and meaning equivalent to the scope of the claims.

What is claimed is:

1. A semiconductor device comprising:
a base member made of a conductive material;
a first semiconductor element connected to the base member by a bonding material; and
a second semiconductor element connected to the base member by the bonding material and having a planar size smaller than that of the first semiconductor element, wherein
the first semiconductor element and the second semiconductor element are arranged in a first direction,
in the base member, a first groove is formed to surround the first semiconductor element,
in the base member, a second groove is formed to surround the second semiconductor element,
the first groove and the second groove overlap each other in a region between the first semiconductor element and the second semiconductor element, and
in a second direction which is a direction orthogonal to the first direction, a distance between portions of the second groove disposed to sandwich the second semiconductor element is smaller than a distance between portions of the first groove disposed to sandwich the first semiconductor element.

2. The semiconductor device according to claim 1, comprising:
a terminal;
a connection portion to electrically connect the terminal and the base member; and
an insulating resin to cover the base member and the connection portion, wherein
the terminal protrudes from the resin, and
in the first direction, a distance from the connection portion to the second groove is larger than a distance from the connection portion to the first groove.

3. The semiconductor device according to claim 2, wherein
the base member and the connection portion are separate bodies, and
the base member and the connection portion are bonded via solder or an alloy layer.

4. The semiconductor device according to claim 2, wherein the base member and the connection portion are made of an integral metal member.

5. The semiconductor device according to claim 1, wherein, in the second direction, a distance between an end portion of the base member and the second groove is larger than a distance between the end portion of the base member and the first groove.

6. The semiconductor device according to claim 1, wherein, in the second direction, a distance between one end portion of the base member and the second groove is different from a distance between another end portion of the base member and the second groove.

7. The semiconductor device according to claim 1, wherein cross sectional shapes of the first groove and the second groove are a V-shape.

8. The semiconductor device according to claim 1, comprising a third semiconductor element to control at least one of the first semiconductor element and the second semiconductor element, wherein
in the first direction, a distance from the third semiconductor element to the second groove is smaller than a distance from the third semiconductor element to the first groove, and
in the first direction, a distance between portions of the second groove disposed to sandwich the second semiconductor element is smaller than a distance between portions of the first groove disposed to sandwich the first semiconductor element.

9. The semiconductor device according to claim 8, comprising:
a main current wire to electrically connect the first semiconductor element and the second semiconductor element, and
a control wire to electrically connect one of the first semiconductor element and the second semiconductor element to the third semiconductor element, wherein
a cross sectional area of the control wire is smaller than a cross sectional area of the main current wire.
